(19) United States
(12) Patent Application Publication
(10) Pub. No.: US 2009/0045456 A1
(43) Pub. Date: Feb. 19, 2009

(54) SEMICONDUCTOR DEVICE AND METHOD OF FABRICATING THE SAME

(75) Inventors: Hsuan-Hsu Chen, Tainan City (TW); Hsin-Chi Chen, Tainan County (TW); Jiunn-Hsiung Liao, Tainan County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/837,746

(22) Filed: Aug. 13, 2007

(51) Int. Cl. H01L 31/0312; H01L 21/336; H01L 29/76

(52) U.S. Cl. 257/327; 257/77; 438/285; 257/E31.023; 257/E21.409

(57) ABSTRACT

A method of fabricating a semiconductor device is provided. The method includes forming a gate structure on a substrate. The gate structure includes a patterned gate dielectric layer, a patterned gate conductor layer, a cap layer and a spacer. Next, a first and a second recesses are formed in the substrate on the two sides of the gate structure. Thereafter, a protection layer is formed on the bottom surfaces of the first and the second recesses, and then a etching process is performed to laterally enlarge first and the second recesses towards the direction of the gate structure. Thereafter, a material layer is respectively formed in the first recess and the second recess. Afterward, two source/drain contact regions are respectively formed in the material layers of the first recess and the second recess.

### BACKGROUND OF THE INVENTION

1. Field of the Invention

The present invention relates to an integrated circuit and a method of fabricating the same, and more particularly, to a semiconductor device and a method of fabricating the same.

2. Description of Related Art

A metal-oxide semiconductor (MOS) transistor is a basic structure extensively adopted by a variety of semiconductor devices such as memory devices, image sensors, or display devices. A typical MOS transistor includes a silicon dioxide dielectric layer, a gate conductor layer, and a heavily doped source/drain contact region. The size of a semiconductor device is reduced as the line width of the semiconductor device is reduced. As a result, the width of the gate in a conventional MOS transistor and the channel length within the MOS transistor are also reduced. Since the threshold voltage is decreased and the sub-threshold current is increased, a short channel effect is resulted. On the other hand, as the gate width is reduced, the electric field between the source and the drain is increased. Consequently, a hot carrier effect is generated. Hence, an electrical breakdown effect is resulted due to the abundant generation of carriers in the channel near the drain region. To prevent a punch-through effect, the channel needs to be of a certain length. Otherwise, the MOS transistor fabricated cannot be utilized.

To overcome the above-mentioned shortcomings, one of the solutions is to adopt a lightly doped drain (LDD). More specifically, the lightly doped drain method involves decreasing the doping concentration of the source/drain region near the channel to form a lightly doped drain region in order to reduce the occurrence of hot electron effect caused by an increase in the electric field between the source and the drain. Since the doping concentration of the lightly doped region is low, the lightly doped region has a higher resistance. Consequently, the electron mobility in the channel region is decreased and the operating speed of the device is reduced, increasing the power consumption.

The mechanical stress in the channel is controlled to adjust the mobility of the electrons and holes in the channel, which is a way to increase the operating speed of the transistor. Prior art has proposed using silicon germanium as the major component of the source/drain region of a transistor. In comparison with silicon, germanium has a larger atomic volume. Thus, the mobility of holes in a SiGe-based source/drain region can be enhanced, and the device performance can also be improved. A conventional method includes performing a single-step etching process to remove the portion of the substrate that is pre-designated for the formation of the source/drain contact region, forming a recess. Thereafter, a selective area epitaxial growth is performed to fill the recess with silicon germanium. Nevertheless, it is harder to effectively control the depth and the width of a recess formed by a single-step etching process. Therefore, a transistor fabricated using the single-step etching process may result in undesired problems such as a distance between the source region and the drain region that is too long or a depth of the junction between the source contact region and the drain contact region that is too deep.

### SUMMARY OF THE INVENTION

The present invention is directed to a semiconductor device and a method of fabricating the same adapted for effectively reducing the distance between the source region and the drain region, and effectively controlling the depth of the junction between the source region and the drain region.

The present invention is directed to a method of fabricating a semiconductor device. The method includes the following steps. First, a gate structure is formed on a substrate, and the gate structure includes a patterned gate dielectric layer, a patterned gate conductor layer, a cap layer, and a spacer. Next, a first etching process is performed to form a first recess and a second recess in the substrate on the two sides of the gate structure. Next, a protection layer is respectively formed in the bottom surfaces of the first recess and the second recess. Thereafter, a second etching process is performed to laterally etch the substrate on the sides of the first recess and the second recess to laterally enlarge the first recess and the second recess towards the direction of the gate structure. Afterward, a material layer is respectively formed in the first recess and the second recess. Subsequently, a source/drain contact region is respectively formed in the respective material layer of the first recess and the second recess.

According to an embodiment of the present invention, the method of fabricating the semiconductor device further includes a step of removing the protection layer before the material layer is formed and after the second etching process is performed.

According to an embodiment of the present invention, the first etching process includes an isotropic etching process or an anisotropic etching process.

According to an embodiment of the present invention, the second etching process includes an isotropic etching process or an anisotropic etching process.

According to an embodiment of the present invention, the first etching process includes an anisotropic etching process; the second etching process includes an isotropic etching process.

According to an embodiment of the present invention, the second etching process is the same as the first etching process.

According to an embodiment of the present invention, the second etching process is different from the first etching process.

According to an embodiment of the present invention, prior to forming the material, the method of fabricating the semiconductor device further includes at least a step of forming another protection layer on the bottom surfaces of the first recess and the second recess, and repeating the step of performing the second etching process.

According to an embodiment of the present invention, the protection layer includes a silicon oxide layer, a silicon nitride layer, a silicon oxynitride layer, or a silicon carbide layer.

According to another embodiment of the present invention, the first etching process and the second etching process are performed in different machines.

According to an embodiment of the present invention, when the first etching process is a dry etching process, the protection layer is formed in situ in the same machine where the first etching process is performed.

According to an embodiment of the present invention, when the second etching process is a dry etching process, the protection layer is formed in situ in the same machine where the second etching process is performed.

According to an embodiment of the present invention, when the first etching process and the second etching process are dry etching processes, the protection layer is formed in situ in the same machine where the first etching process is performed, or in situ in the same machine where the second etching process is performed, or in situ in the same machine where the first etching process and the second etching process are performed.

According to an embodiment of the present invention, the spacer includes an offset spacer.

According to an embodiment of the present invention, the spacer includes an offset spacer and a first spacer. Herein, the offset spacer is disposed on the sidewall of the patterned gate dielectric layer and the patterned gate conductor layer. Further, the first spacer is disposed on the outer side of the offset spacer.

According to an embodiment of the present invention, the spacer includes an offset spacer, a first spacer, and a second spacer. The offset spacer is disposed on the sidewall of the patterned gate dielectric layer and the patterned gate conductor layer. The second spacer is disposed on the outer side of the offset spacer. The first spacer is disposed between the offset spacer and the second spacer.

According to an embodiment of the present invention, after lateral enlargement is performed, the distance between the border of the first recess and the second recess and the sidewall of the patterned gate conductor layer is 160±20 Å.

According to an embodiment of the present invention, the method for fabricating the semiconductor device further includes forming a source/drain extension region in the substrate on the two sides of the patterned gate conductor layer.

According to an embodiment of the present invention, the material layer is a semiconductor compound layer.

According to an embodiment of the present invention, the method for forming the semiconductor compound layer includes a selective area epitaxial growth.

According to an embodiment of the present invention, the material of the semiconductor compound includes silicon germanium or silicon carbide.

The present invention is directed to a semiconductor device including a substrate, a patterned gate dielectric layer, a patterned gate conductor layer, a spacer, a material layer, and two source/drain contact regions. The substrate includes a first recess and a second recess. The patterned gate dielectric layer is disposed on the substrate between the first recess and the second recess. The patterned gate conductor layer is disposed on the gate dielectric layer. The distance between the sidewall of the patterned gate conductor layer and the border of the first recess or that of the second recess is 160±20 Å. The material layer is disposed in the first recess and the second recess. The spacer is disposed over the sidewall of the gate conductor layer and a portion of the material layer in the first recess and the second recess. The two source/drain contact regions are respectively disposed in the material layers of the first recess and the second recess.

According to an embodiment of the present invention, the portion of the material layer that is not covered by the spacer protrudes more from the surface of the substrate compared to the portion of the material layer that is below the spacer.

According to an embodiment of the present invention, the spacer includes an offset spacer.

According to an embodiment of the present invention, the spacer includes an offset spacer and a first spacer. Herein, the offset spacer is disposed on the patterned gate dielectric layer and the sidewall of the patterned gate conductor layer. Further, the first spacer is disposed on the outer side of the offset spacer.

According to an embodiment of the present invention, the spacer includes an offset spacer, a first spacer, and a second spacer. The offset spacer is disposed on the sidewall of the patterned gate dielectric layer and the patterned gate conductor layer. The second spacer is disposed on the outer side of the offset spacer. The first spacer is disposed between the offset spacer and the second spacer.

According to an embodiment of the present invention, the material used for fabricating the material layer formed in the first recess and the second recess is different from the material used for fabricating the substrate.

According to an embodiment of the present invention, the material layer is a semiconductor compound layer.

According to an embodiment of the present invention, the semiconductor compound layer includes a silicon germanium epitaxial layer or a silicon carbide epitaxial layer.

According to an embodiment of the present invention, the semiconductor device further includes two source/drain extension regions that are respectively disposed in the substrate between the patterned gate conductor layer and the source/drain contact region.

According to the present invention, at least two etching processes and a formation of the protection layer are used to form the recess of the source/drain contact region. Further, the protection layer formed between the two etching processes can be formed in situ in the same machine where the etching process is performed, making the overall fabrication process very simple.

The present invention is directed to a semiconductor device and a method of fabricating the same adapted for effectively reducing the distance between the source region and the drain region, and effectively controlling the depth of the junction between the source region and the drain region.

In order to the make the aforementioned and other objects, features and advantages of the present invention comprehensible, several embodiments accompanied with figures are described in detail below.

### BRIEF DESCRIPTION OF THE DRAWINGS

FIGS. 1 through 5 are cross-sectional views schematically illustrating the steps for fabricating a metal-oxide semiconductor device according to an embodiment of the present invention.

FIG. 1A is a cross-sectional view schematically illustrating another semiconductor device during fabrication according to an embodiment of the present invention.

FIG. 1B is a cross-sectional view schematically illustrating another semiconductor device during fabrication according to an embodiment of the present invention.

FIG. 1C is a cross-sectional view schematically illustrating another semiconductor device during fabrication according to an embodiment of the present invention.

FIG. 2A is a cross-sectional view schematically illustrating another semiconductor device during fabrication according to an embodiment of the present invention.

### DESCRIPTION OF EMBODIMENTS

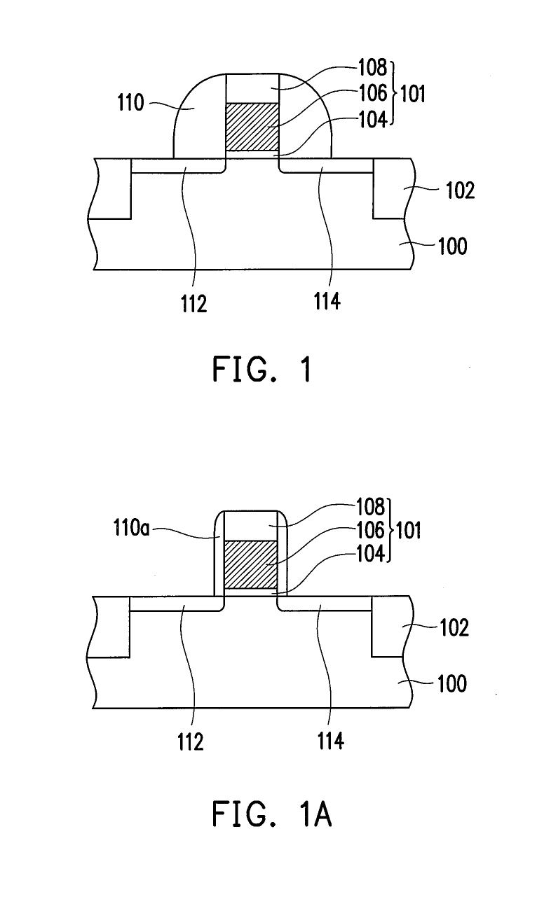

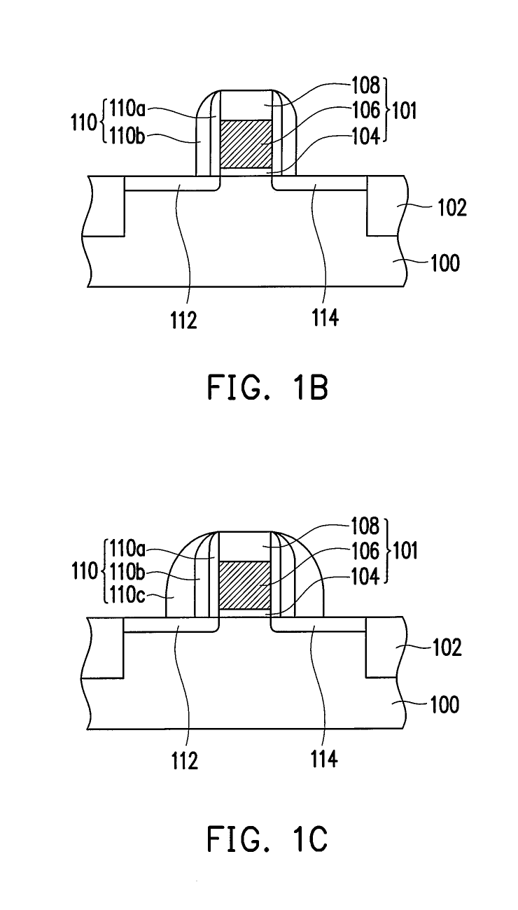

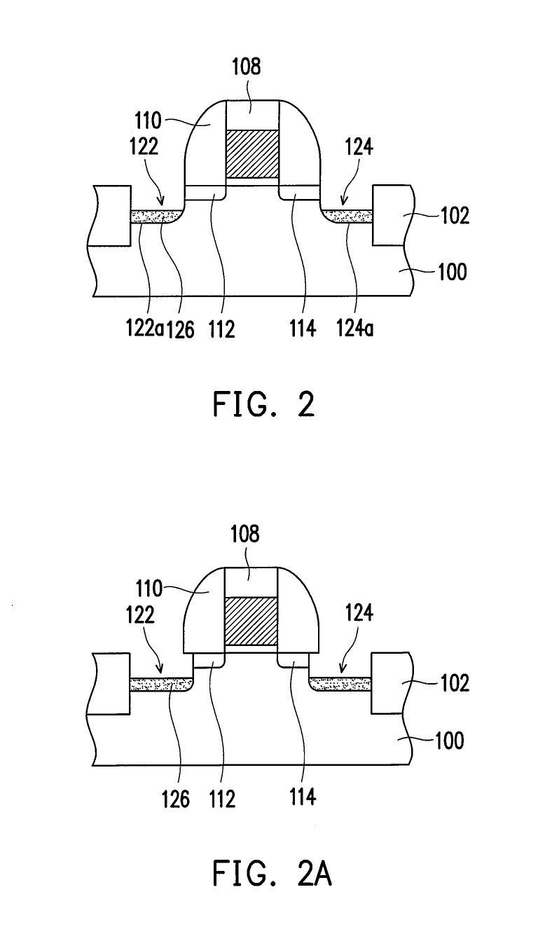

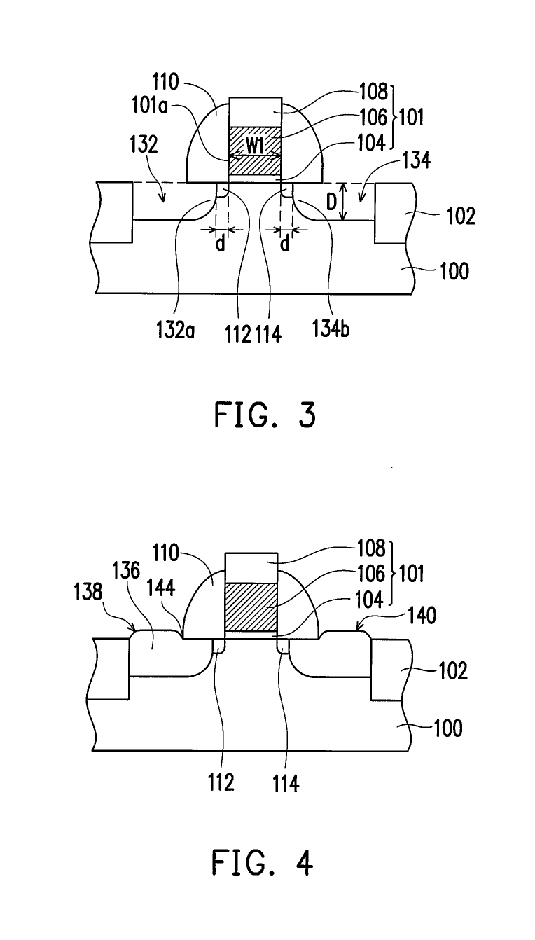

Referring to FIG. 1, a substrate 100 is provided. The substrate 100 may be, for example, a bulk-Si substrate or a silicon-on-insulator (SOI) substrate. In an embodiment, the substrate 100 includes P-type silicon. In an embodiment, a well region, such as an N-type well and/or a P-type well (not shown), is formed in the substrate 100. Next, an isolation structure 102 is formed in the substrate 100. The method for forming the isolation structure is, for example, a shallow trench isolation (STI) process.

Next, a gate structure 101 is formed on the substrate 100. The gate structure 101 includes a patterned gate dielectric layer 104, a patterned gate conductor layer 106, a patterned cap layer 108, and a spacer 110. The material of the gate dielectric layer 104 is, for example, silicon oxide, and the method of forming the gate dielectric layer 104 is, for example, a thermal oxidation process. The material of the gate conductor layer 106 includes a silicon-based material such as doped silicon, undoped silicon, doped polysilicon or undoped polysilicon. When the material of the gate conductor layer 106 is doped silicon or doped polysilicon, the dopant used to dope the silicon or the polysilicon may be N-type or P-type. The material of the cap layer 108 is, for example, silicon oxide, and the method used for forming the cap layer 108 is, for example, a chemical vapor deposition process.

Thereafter, a source/drain extension region 112 and a source/drain extension region 114 are formed in the substrate 100 on the two sides of the gate conductor layer 106. Further, the source/drain extension region 112 and the source/drain extension region 114 may be N-type or P-type. The N-type dopant is, for example, phosphorous (P) or arsenic (As). The P-type dopant is, for example, boron (B). The source/drain extension region 112 and the source/drain extension region 114 may be formed by an ion implantation process.

Referring to FIG. 1, a spacer 110 is formed on the sidewall of the gate conductor layer 106. The material used for fabricating the spacer 110 is, for example, silicon oxide or silicon nitride. The thickness of the spacer 110 is, for example, about 410˜450 Å. In another embodiment, the spacer 110 may be an offset spacer 110a as shown in FIG. 1A. The material used for fabricating the offset spacer 110a is, for example, silicon oxide. The thickness of the offset spacer 110a is, for example, about 50˜60 Å. In yet another embodiment, the spacer 110 includes an offset spacer 110a and a single-layered spacer 110b as shown in FIG. 1B. The material used for fabricating the spacer 110a is, for example, silicon oxide. The thickness of the offset spacer 110a is, for example, about 50˜60 Å. The material used for fabricating the spacer 110b is, for example, silicon oxide or silicon nitride, which may be the same as or different from the material used for fabricating the offset spacer 110a. The thickness of the spacer 110b is, for example, 150˜200 Å. The shapes of the offset spacer 110a and the spacer 110b are not limited to what are shown in the figures. More specifically, the shapes of the offset spacer 110a and that of the spacer 110b can be any other shapes. Referring to FIG. 1C, in yet another embodiment, a spacer 110 includes an offset offset spacer 110a, and a double-layered spacer 110b and 110c. The material used for fabricating the spacer 110a is, for example, silicon oxide. The thickness of the offset spacer 110a is, for example, about 50˜60 Å. The material used for fabricating the spacer 110b is, for example, silicon oxide or silicon nitride, which may be the same as or different from the material used for fabricating the offset spacer. The thickness of the spacer 110b is, for example, about 150˜200 Å. The material used for fabricating the spacer 110c is, for example, silicon oxide or silicon nitride, which may be the same as or different from the material used for fabricating the offset spacer 110a. The thickness of the spacer 110c is, for example, about 300˜350 Å. In an embodiment, the materials used for fabricating a three-layer structure of offset spacer 110a/spacer 110b/spacer 110c are silicon oxide/silicon nitride/silicon oxide. The shapes of the offset spacer 110a and the spacers 110b and 110c are not limited to what are shown in the figures. More specifically, the shapes of the offset spacer 110a and the spacers 110b and 110c can be any other shapes.

For the convenience of description, the following steps are described based on the spacer 110 shown in FIG. 1. However, the present invention is not limited thereto.

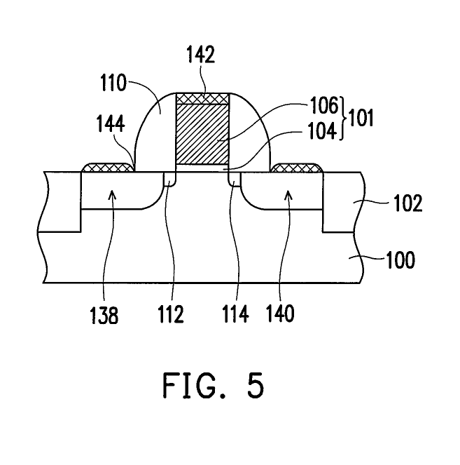

Referring to FIG. 2, the cap layer 108 and the spacer 110 are used as a mask. A first etching process is performed to etch the substrate 100 on the two sides of the gate structure 101 to form a recess 122 and a recess 124. The first etching process includes an anisotropic etching process or an isotropic etching process.

When the first etching process is an anisotropic etching process, it includes a dry etching process. In an embodiment, the dry etching process is, for example, a plasma etching process. Further, the reactive gas used consists of fluorinated hydrocarbons such as CF₄ and CHF₃; the flow rate varies from 100 sccm to 125 sccm; the operating pressure is about 4 mT; the operating temperature is about 40° C.; and the reaction time is about 13 seconds.

When the first etching process is an isotropic etching process, it is, for example, a dry etching process. In an embodiment, the dry etching process is a plasma etching process. Further, the reactive gas used includes NF₃, O₂, and Cl₂; the flow rates for NF₃, O₂, and Cl₂ are 30 sccm, 6 sccm, and 50 sccm; the operating pressure is about 15 mT; the power is about 750 watt; the operating temperature is about 40° C.; the reaction time is about 13 seconds; and the bias voltage is 0.

When the first etching process is an anisotropic etching process, it may be a wet etching process. The wet etching process uses, for example, buffer oxide etcher (BOE) as an etchant.

In an embodiment, the first etching process is an anisotropic etching process. More specifically, the etching gas substantially etches the substrate 100 horizontally to form a recess 122 and a recess 124 along the outer side of the spacer 110 as shown in FIG. 2.

Referring to FIG. 2A, in another embodiment, the first etching process is an isotropic etching process. Further, the etching gas substantially etches the substrate 100 both horizontally and laterally to form a recess 122 and a recess 124 that undercut below the spacer 110.

Referring to FIG. 2, a protection layer 126 is formed on the bottom surface 122a of the recess 122 and the bottom surface 124a of the recess 124. The protection layer 126 includes a silicon oxide layer, a silicon nitride layer, a silicon oxynitride layer or a silicon carbide layer. In an embodiment, the protection layer 126 is a silicon oxide layer. Specifically, the protection layer is formed by introducing oxygen and argon into the reaction chamber. Further the flow rates for oxygen and argon respectively are about 6 sccm and about 200 sccm; the operating pressure is approximately 4 mT; the operating temperature about 40° C.; and the reaction time is approximately 20 seconds. In an embodiment, the protection layer 126 is a silicon oxide layer. Specifically, the protection layer is formed by introducing nitrogen-containing gases such as nitrogen and argon into the reaction chamber. Further the flow rates for nitrogen and argon respectively are about 6 sccm and about 200 sccm; the operating pressure is approximately 4 mT; the operating temperature about 40° C.; and the reaction time is approximately 20 seconds.

Referring to FIG. 3, a second etching process is performed to laterally etch substrate 100 on the sidewalls of the recess 122 and the recess 124. The bottom surface 122a of the recess 122 and the bottom surface 124a of the recess 124 are covered by the protection layer 126 (as shown in FIG. 2). Therefore, the second etching process laterally enlarges the recess 122 and the recess 124 towards the direction of the gate structure 101 to form a recess 132 and a recess 134. During the second etching process, the protection layer 126 protects the bottom surfaces of the recess 132 and of the recess 134. If the protection layer 126 is thick enough, a portion of the protection layer 126 remains on the recess 132 and the recess 134 after the second etching process is performed. Hence, the depths of the recess 132 and the recess 134 may remain unchanged. If the protection layer 126 is thinner, the protection layer 126 is depleted from the recess 132 and the recess 134 after the second etching process is performed. Even a portion of the substrate 100 on the bottom surfaces of the recess 132 and the recess 134 is removed by the etching process. Nevertheless, the level of the vertical etch is reduced to achieve lateral enlargement.

The second etching process may be the same as or different from the first etching process. The second etching process includes an anisotropic etching process or an isotropic etching process. When the second etching process is an anisotropic etching process, it is, for example, a dry etching process. In an embodiment, the dry etching process is a plasma etching process. Further, the reactive gas used includes NF₃, O₂, Cl₂, and Ar; the flow rates for NF₃, O₂, Cl₂, and Ar respectively are 50 sccm, 10 sccm, 80 sccm, and 200 sccm; the operating pressure is about 15 mT; the power is about 500 watt; the operating temperature is about 40° C.; the reaction time is about 5 seconds; and the bias voltage is 0.

If the second etching process is an isotropic etching process, it may be a wet etching process. The wet etching process uses, for example, BOE as an etchant.

The said first etching process and the said second etching process may be performed in the same machine or in different machines. When the first etching process and the second etching process are performed in the same machine, the protection layer 126 is formed in situ in the same machine where the etching process is performed, or ex situ in a machine that is different from the one where the etching process is performed. When the first etching process and the second etching process are performed in different machines, the protection layer 126 may be formed in situ in the same machine where the first etching process is performed, or in situ in the same machine where the second etching process is performed, or ex situ in a machine that is different from the one where the first and the second etching processes are performed.

In an embodiment, the first etching process and the second etching process are performed in different machines. Further, the first etching process is a dry etching process, and the second etching process is a wet etching process. Additionally, the protection layer 126 is formed in situ in the same machine where the first etching process is performed.

In another embodiment, the first etching process and the second etching process are performed in different machines. Further, the first etching process is a wet etching process, and the second etching process is a dry etching process. Additionally, the protection layer 126 is formed in situ in the same machine where the second etching process is performed.

In yet another embodiment of the present invention, when the first etching process and the second etching process are dry etching processes, the protection layer 126 is formed in situ in the same machine where the first etching process is performed, or in situ in the same machine where the second etching process is performed, or in situ or ex situ in the same machine where the first etching process and the second etching process are performed.

During the second etching process, the protection layer 126 is also etched. After the second etching process is performed, if there is still any protection layer 126 remained, the remaining protection layer 126 is further removed to expose the recess 132 and the recess 134. The method for removing the protection layer 126 is, for example, a dry etching process. The protection layer 126 may be removed in situ in the same machine where the second etching process is performed or ex situ in a machine that is different from the one where the second etching process is performed. In an embodiment, the width W1 of the gate structure 101 is 320±50 Å; the depth of the recesses 132 and 134 is 650±50 Å; the distance d between the border 132b of the recess 132 and the border 134b of the recess 134 and the sidewall 101a of the gate structure 101 is 160±20 Å.

Referring to FIG. 4, a material layer 136 is formed in the recess 132 and the recess 134, and then doped to form source/drain contact regions 138 and 140. The material used for fabricating the material layer 136 is, for example, silicon or semiconductor compound such as silicon germanium or silicon carbide, and the method used for fabricating the same may be a selective area epitaxial growth to form a silicon epitaxial layer, a silicon germanium epitaxial layer, or a silicon carbide epitaxial layer. In an embodiment, the material layer 136 in the recess 132 and the recess 134 protrudes from the surface of the substrate 100. More specifically, the material layer 136 in the recess 132 and the recess 134 protrudes from the surface of the substrate 100 starting from a portion 144 that is not covered by the spacer 110. Or, the portion that is not covered by the spacer 110 or the portion that is covered by the spacer 110 protrudes from the surface of the substrate 100. However, the portion that is not covered by the spacer 110 protrudes more from the surface of the substrate 100 compared to the portion that is covered by the spacer 110. It is because, during the epitaxial growth process, the portion of the material layer 136 below the spacer 110 is refrained from growing upward by the spacer 110 above it, and the portion of the material layer 136 that is not covered by the spacer 110 grows upward and protrudes from the surface of the substrate 100 because there is no spacer 110 above it.

Source/drain contact regions 138 and 140 are formed in situ in the formation of the material layer 136 or by an ion implantation process after the material layer 136 is formed. The dopant used to dope the material layer 136 may be n-type or p-type. The N-type dopant is, for example, phosphorous (P) or arsenic (As). The P-type dopant is, for example, boron (B). In an embodiment, the substrate 100 is a bulk-Si substrate, the material layer 136 is silicon germanium, the source/drain contact regions 138 and 140 are P-type. In another embodiment, the substrate 100 is a bulk-Si substarte, the material layer 136 is silicon carbide, the source/drain contact regions 138 and 140 are N-type.

Thereafter, as shown in FIG. 5, the cap layer 108 is removed. The method used to remove the cap layer 108 may be a wet etching process that uses diluted hydrofluoric acid as the etchantNext, a metal silicide layer 142 is respectively formed on the source/drain contact regions 138 and 140, and the gate conductor layer 106 to lower the resistance. The metal silicide layer 142 includes a metal silicide with a refractory metal selected from the group consisting of nickel, cobalt, titanium, copper, molybdenum, tantalum, tungsten, erbium, zirconium, platinum and an alloy comprising one or more of these metals.

The foregoing embodiments are described based on forming a protection layer once and performing the second etching process once after the protection layer is formed. However, the present invention is not limited thereto. The formation of the protection layer and the second etching process may be repeated multiple times to ensure the substrate is not etched vertically in the depth direction of the recess formed or only minimal substrate is etched vertically in the depth direction of the recess, and the recess is etched laterally towards the direction of the gate structure in order to ensure the border of the final recess meets the requirement.

The present invention includes performing at least two etching processes and forming a protection layer prior to the second etching process. The first etching process may form a recess with a pre-designated depth in the substrate on the two sides of the gate. The bottom surface of the recess formed by the first etching process is covered by the protection layer to protect the bottom surface of the recess during the second etching process. During the second etching process, the depth of the recess is maintained or the level of the vertical etch is reduced because of the presence of the protection layer, ensuring the recess formed during the first etching process is enlarged laterally towards the direction of the gate structure. Hence, the present invention can effectively control the depth and width of the recess as desired. Therefore, a semiconductor device formed according to the method of the present invention can reduce the distance between two recesses and increase stress by forming a material layer in the two recesses in order to improve the performance of the device.

The process of forming a recess and the steps for forming a protection layer according to the embodiments of the present invention are fairly simple. In other words, the present invention uses simple steps to control the depth and the width of the recess.

What is claimed is:

1. A method of fabricating a semiconductor device, comprising:
forming a gate structure on a substrate, wherein the gate structure comprises a patterned gate dielectric layer, a patterned gate conductor layer, a cap layer, and a spacer;
performing a first etching process to form a first recess and a second recess in the substrate on the two sides of the gate structure;
forming a protection layer on the bottom surfaces of the first recess and the second recess;
performing a second etching process to laterally etch the substrate on the sides of the first recess and the second recess to laterally enlarge the first recess and the second recess towards the direction of the gate structure;
forming a material layer respectively in the first recess and the second recess; and
forming a source/drain contact region in the respective material layer of the first recess and the second recess.

2. The method of claim 1, wherein the method further includes a step of removing the protection layer before the material layer is formed and after the second etching process is performed.

3. The method of claim 1, wherein the first etching process comprises an isotropic etching process or an anisotropic etching process.

4. The method of claim 1, wherein the second etching process comprises an isotropic etching process or an anisotropic etching process.

5. The method of claim 1, wherein the first etching process comprises an anisotropic etching process, and the second etching process comprises an isotropic etching process.

6. The method of claim 1, wherein the steps for performing the second etching process are the same as the steps for performing the first etching process.

7. The method of claim 1, wherein the steps for performing the second etching process are different from the steps for performing the first etching process.

8. The method of claim 1, wherein the method further comprises at least a step of forming another protection layer on the bottom surfaces of the first recess and the second recess, and repeating the step of performing the second etching process prior to proceeding to step of forming the material.

9. The method of claim 1, wherein the protection layer comprises a silicon oxide layer, a silicon nitride layer, a silicon oxynitride layer or a silicon carbide layer.

10. The method of claim 1, wherein the first etching process and the second etching process are performed in different machines.

11. The method of claim 10, wherein the protection layer is formed in situ in the same machine where the first etching process is performed when the first etching process is a dry etching process.

12. The method of claim 10, wherein the protection layer is formed in situ in the same machine where the second etching process is performed when the second etching process is a dry etching process.

13. The method of claim 1, wherein the protection layer is formed in situ in the same machine where the first etching process is performed, or the protection layer is formed in situ in the same machine where the second etching process is performed, or the protection layer is formed in situ in the same machine where the first etching process and the second etching process are performed, when the first etching process and the second etching process are dry etching processes.

14. The method of claim 1, wherein the spacer comprises an offset spacer.

15. The method of claim 1, wherein the spacer comprises:
an offset spacer disposed on the sidewalls of the patterned gate dielectric layer and the patterned gate conductor layer; and
a first spacer disposed on the outer side of the offset spacer.

16. The method of claim 1, wherein the spacer comprises:
an offset spacer disposed on the sidewalls of the patterned gate dielectric layer and the patterned gate conductor layer;
a first spacer; and
a second spacer disposed on the outer side of the offset spacer, wherein the first spacer is disposed between the offset spacer and the second spacer.

17. The method of claim 1, wherein the distance between a border of the first recess and the second recess and the sidewall of the patterned gate conductor layer is 160±20 Å after the lateral enlargement is performed.

18. The method of claim 1, wherein the method further comprises forming a source/drain extension region in the substrate on the two sides of the patterned gate conductor layer.

19. The method of claim 1, wherein the material layer is a semiconductor compound layer.

20. The method of claim 19, wherein the method for forming the semiconductor compound layer comprises a selective area epitaxial growth.

21. The method of claim 19, wherein the material used for forming the semiconductor layer comprises silicon germanium or silicon carbide.

22. A semiconductor device, comprising:
a substrate comprising a first recess and a second recess;
a patterned gate dielectric layer disposed on the substrate between the first recess and the second recess;
a patterned gate conductor layer disposed on the gate dielectric layer, wherein the distance between the sidewall of the patterned gate conductor layer and a border of the first recess or the second recess is 160±20 Å;
a material layer disposed in the first recess and the second recess;
a spacer disposed over the sidewall of the gate conductor layer and a portion of the material layer in the first recess and the second recess; and
two source/drain contact regions respectively disposed in the material layer of the first recess and the second recess.

23. The device of claim 22, wherein the material layer that is not covered by the spacer protrudes more from the surface of the substrate compared to the material layer below the spacer.

24. The device of claim 22, wherein the spacer is an offset spacer.

25. The device of claim 22, wherein the spacer comprises:
an offset spacer disposed on the sidewall of the patterned gate dielectric layer and the patterned gate conductor layer; and
a first spacer disposed on the outer side of the offset spacer.

26. The device of claim 22, wherein the spacer comprises:
an offset spacer disposed on the patterned gate dielectric layer and the sidewall of the patterned gate conductor layer;
a first spacer; and
a second spacer disposed on the outer side of the offset spacer, wherein the first spacer is disposed between the offset spacer and the second spacer.

27. The device of claim 22, wherein the material used for forming the material layer in the first recess and the second recess is different from the material used for forming the substrate.

28. The device of claim 27, wherein the material layer is a semiconductor compound layer.

29. The device of claim 28, the semiconductor compound layer comprises a silicon germanium epitaxial layer or a silicon carbide epitaxial layer.

30. The device of claim 22, wherein the semiconductor device further comprises two source/drain region extension regions that are respectively disposed on the patterned gate conductor layer and in the substrate between the source/drain contact regions.
